(19) United States
(12) Patent Application Publication
(10) Pub. No.: US 2011/0101201 A1
(43) Pub. Date: May 5, 2011

(54) Photodetector Array Having Electron Lens

(76) Inventors: Vincent Venezia, Sunnyvale, CA (US); Duli Mao, Sunnyvale, CA (US); Dyson Tai, Cupertino, CA (US); Yin Qian, Milpitas, CA (US)

(21) Appl. No.: 12/612,594

(22) Filed: Nov. 4, 2009

(51) Int. Cl. H01J 40/02; H01L 31/0232; H01L 21/77

(52) U.S. Cl. 250/200; 257/432; 438/73; 257/E31.127; 257/E21.598

(57) ABSTRACT

Photodetectors, photodetector arrays, image sensors, and other apparatus are disclosed. An apparatus, of one aspect, may include a surface to receive light, a photosensitive region disposed within a substrate, and a material coupled between the surface and the photosensitive region. The material may receive the light. At least some of the light may free electrons in the material. An electron lens coupled between the surface and the material may focus the electrons in the material toward the photosensitive region. Other apparatus are also disclosed, as are methods of using such apparatus, methods of fabricating such apparatus, and systems incorporating such apparatus.

### BACKGROUND

### Background Information

Image sensors are prevalent. The image sensors may be used in a wide variety of applications, such as, for example, digital still cameras, cellular phones, digital camera phones, security cameras, optical mice, as well as various other medical, automobile, military, or other applications.

Crosstalk is one challenge encountered by many image sensors. Two common forms of crosstalk are electrical crosstalk and optical crosstalk.

Electrical crosstalk may occur, for example, when an electron generated in a region corresponding to one photosensitive region diffuses, laterally drifts, or otherwise migrates or moves to and is collected by a neighboring photosensitive region. The electrons may end up being collected by the neighboring photosensitive region.

Optical crosstalk may occur, for example, when light incident upon a surface corresponding to one photosensitive region is refracted, reflected, scattered, or otherwise directed to a neighboring photosensitive region. The light may end up being detected by the neighboring photosensitive region.

Such crosstalk tends to be undesirable, since it may tend to blur images, introduce artifacts, or otherwise reduce image quality. In addition, such crosstalk may tend to become a bigger challenge as the size of the image sensors and their pixels continues to decrease.

Image sensors having reduced optical and/or electrical crosstalk would offer certain advantages.

### BRIEF DESCRIPTION OF THE SEVERAL VIEWS OF THE DRAWINGS

The invention may best be understood by referring to the following description and accompanying drawings that are used to illustrate embodiments of the invention. In the drawings:

FIG. 1 is a cross-sectional side view of photodetector, according to embodiments of the invention.

FIG. 2 is a block flow diagram of a method of using a photodetector, according to embodiments of the invention.

FIG. 3 is a cross-sectional side view of a photodetector array, according to one or more embodiments of the invention.

FIG. 4 is a cross-sectional side view of another photodetector array, according to one or more embodiments of the invention.

FIG. 5 is a cross-sectional side view of yet another photodetector array, according to one or more embodiments of the invention.

FIG. 6 is a block flow diagram of a method of making or fabricating a photodetector array, according to embodiments of the invention.

FIGS. 7A to 7E illustrate various structures formed while carrying out the method of FIG. 6, according to one or more embodiments of the invention.

FIGS. 8A to 8E illustrate various structures formed while carrying out the method of FIG. 6, according to one or more other embodiments of the invention.

FIG. 9 is a circuit diagram illustrating example pixel circuitry of two pixels of a photodetector array, according to one or more embodiments of the invention.

FIG. 10 is a block diagram illustrating an image sensor unit, according to one or more embodiments of the invention.

FIG. 11 is a block diagram illustrating an illumination and image capture system incorporating an image sensor, according to one or more embodiments of the invention.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure the understanding of this description.

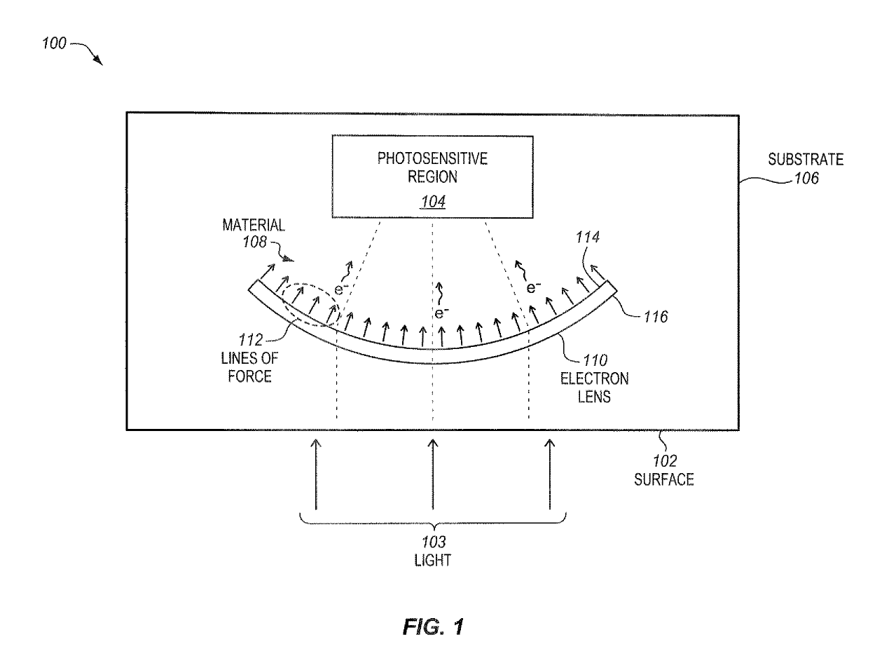

FIG. 1 is a cross-sectional side view of a photodetector 100, according to embodiments of the invention. In various embodiments, the photodetector may include a photodetector array or an image sensor.

The photodetector includes a light collection surface 102, such as, for example, a surface of one or more lenses. During operation, the light collection surface may receive light 103.

The light sensor also includes a photosensitive region 104. The photosensitive region is disposed within a substrate 106. As used herein, a photosensitive region disposed within a substrate is intended to encompass a photosensitive region formed within the substrate, a photosensitive region formed over the substrate, or a photosensitive region formed partly within and partly over the substrate. Typically, the photosensitive region is disposed within a semiconductor material of the substrate. The substrate may also include other materials in addition to semiconductor materials, such as, for example, organic materials, metals, and non-semiconductor dielectrics, to name just a few examples.

Representative examples of suitable photosensitive regions include, but are not limited to, photodiodes, charge-coupled devices (CCDs), quantum device optical detectors, photogates, phototransistors, and photoconductors. Types of photosensitive regions used in complementary metal-oxide-semiconductor (CMOS) active-pixel sensors (APS) are believed to be especially suitable. In one embodiment, the photosensitive region is a photodiode. Representative examples of suitable photodiodes include, but are not limited to, P—N photodiodes, PIN photodiodes, and avalanche photodiodes.

Referring again to FIG. 1, the photodetector also includes a material 108. The material is coupled between the light collection surface 102 and the photosensitive region 104. In one or more embodiments, the material may include a semiconductor material. During operation, the material is to receive the light that was received by the light collection surface 102. The material may transmit the light at least part way toward the photosensitive region 104. Possible paths of the light are shown in dashed lines. The light may or may not go all the way to the photosensitive region, depending upon the material, the thickness of the material, and the wavelength of the light.

Provided that the material has sufficient thickness, at least some of the light may tend to free electrons (e⁻), such as, for example, photoelectrons, in the material. For example, electrons may be generated or freed in a material, such as a semiconductor material, due to the photoelectric effect. In order to be detected, the electrons (e⁻) should move toward the photosensitive region. However, some of the electrons may tend to diffuse, laterally drift, or otherwise move away from the photosensitive region. These electrons may not be detected, which may tend to reduce the efficiency of the photodetector 100.

Notice that the photodetector also includes an electron lens 110, according to embodiments of the invention. The electron lens is coupled between the light collection surface 102 and the material 108. The electron lens may include an electron focusing or converging element, structure, non-flat layer portion, recessed portion of a non-flat surface, concavity, shaped material, or other means for focusing or converging electrons. The electron lens is operable to focus the electrons (e⁻) in the material 108 toward the photosensitive region 104.

In various embodiments, the electron lens may represent a modified portion of the material 108 or a material formed over the material 108. For example, in one or more embodiments, the electron lens may include a more heavily doped region (e.g., a p+ doped region) of a less heavily doped (e.g., a p-type) semiconductor material 108. As another example, in one or more embodiments, the electron lens may include a thin metal layer formed over material 108 in which the metal layer is operable to create a hole accumulation region in an adjacent portion of the material 108 (e.g., a metal flash gate).

The illustrated electron lens has a first major surface 114 closer to the photosensitive region and a second major surface 116 farther from the photosensitive region. In embodiments of the invention, at least one major surface of the electron lens is not flat. In the illustrated electron lens, the first major surface 114 is not flat and includes a recessed surface that recedes away from the photosensitive region. As shown, the recessed surface may include a concave surface facing the photosensitive region. The concave surface may be a hemi-spheroidal surface facing the photosensitive region. The hemi-spheroidal surface may resemble or approximate, but not necessarily be, a hemisphere. In the illustrated electron lens, the second major surface 116 is also not flat, and is convex facing away from the photosensitive region. That is, the illustrated electron lens has a convex-concave shape including the concave surface 114 facing the photosensitive region and a convex surface 116 facing the light collection surface 102 that is to receive the light.

During operation, the electron lens may generate an electric field. The electric field results in converging lines of force 112 operable to act on an electron. The converging lines of force are illustrated as a number of short arrows with tails originating at the electron lens and with heads pointing generally inwardly. The lines of force of the electric field focus or converge generally toward the photosensitive region.

The electron lens may have a focus for the electrons. The focus may represent a focal point or a focus region. The focus may be proximate the photosensitive region. As used herein, for a 2.0 micrometer (μm) pixel or smaller, “proximate” the photosensitive region means within the photosensitive region or within 0.5 μm of the photosensitive region. For larger pixels larger distances may apply. In various embodiments, the focus may be within the photosensitive region, or within 0.3 μm of the photosensitive region (for example in front of the photosensitive region in the material between the electron lens and the photosensitive region, or behind the photosensitive region).

The electric field generated by the electron lens is operable to focus or converge the electrons in the material 108 toward the focus and/or toward the photosensitive region 104. The electric field may repel the electrons or drive them away. Since the electric field is directed inwardly and generally toward the photosensitive region, the electric field may force or encourage the electrons to move inwardly and generally toward the photosensitive region. The electrons are focused inwardly as well as vertically and in three dimensions toward the photosensitive region. Such focusing of the electrons may help to increase the number of electrons collected by the photosensitive region and/or the efficiency of detection. If the electron lens were just a flat structure, the electric field would be parallel and would not focus or converge the electrons.

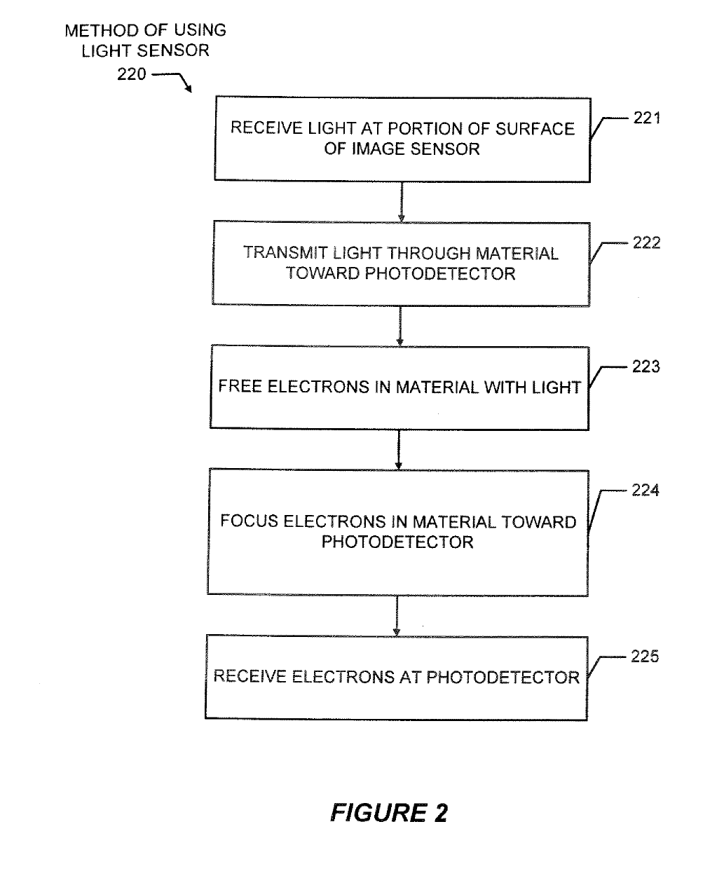

FIG. 2 is a block flow diagram of a method 200 of using a photodetector, according to embodiments of the invention. By way of example, the method may be performed with the photodetector 100 shown in FIG. 1, or one similar.

The method includes receiving light at a light collection surface of the photodetector, at block 221. In one or more embodiments, the photodetector may be a photodetector array used as an image sensor, and the light may be light reflected by an object or surface being imaged, which may be used to generate an image of the object or surface.

The light may be transmitted through a material toward a photosensitive region, at block 222. Electrons may be freed in the material with the light, at block 223. For example, photoelectrons may be freed in the material by the light due to the photoelectric effect.

The electrons in the material may be focused toward the photosensitive region, at block 224. In one or more embodiments, the electrons may be focused toward the photosensitive region in three dimensions with an electric field that drives electrons to converge toward the photosensitive region in three dimensions. As previously discussed, the electron converging electric field may be provided by a non-flat, recessed surface that recedes away from the photosensitive region.

The electrons may be received at the photosensitive region, at block 225. Any remaining light may also be received at the photosensitive region.

As is known, the photosensitive region may generate an analog signal representing the amount of electrons and light collected. The analog signal may be used for various purposes. In some cases, the photodetector may be a photodetector array used as an image sensor and the analog signals may be used to generate an image.

To better illustrate certain concepts, several examples of electron lenses incorporated in particular examples of photodetector arrays will be described below. These particular photodetector arrays are backside illuminated (BSI) photodetector arrays having a particular configuration and particular components. However, it is to be appreciated that the scope of the invention is not limited to these particular photodetector arrays.

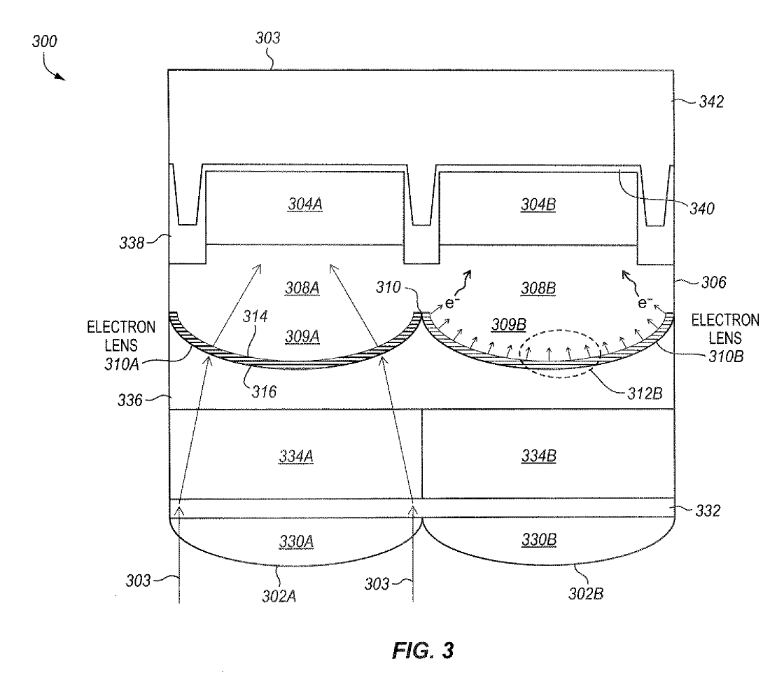

FIG. 3 is a cross-sectional side view of a photodetector array 300, according to one or more embodiments of the invention. The photodetector array is a BSI photodetector array.

Many photodetector arrays today are front side illuminated (FSI). These FSI photodetector arrays include a photodetector array at the front side of a substrate, and during operation the photodetector array receives light from the front side. However, FSI photodetector arrays have certain drawbacks, such as, for example, a limited fill factor.

BSI photodetector arrays are an alternative to FSI photodetector arrays. The BSI photodetector arrays include a photodetector array at the front side of a substrate, and during operation the photodetector array receives light from the backside of the substrate.

Referring again to FIG. 3, the BSI photodetector array includes a front side surface 303 and a backside surface 302A, 302B. The upper and lower sides in FIG. 3 are considered the front and back sides of image sensor 300, respectively. During operation, light 303 may be received at the backside surface.

In one or more embodiments, an optional array of microlenses 330A, 330B may provide the backside surface. The microlenses have diameters that are less than 10 μm. The microlenses are aligned to optically focus the light received at the backside surface toward corresponding photosensitive regions 304A, 304B. The microlenses help to improve sensitivity and reduce optical crosstalk. However, the microlenses are optional, and not required.

The photodetector array also includes an array of photosensitive regions 304A, 304B. The array of photosensitive regions are disposed within a substrate 306. The previously described photosensitive regions are suitable.

The photodetector array also includes a material 308A, 308B, such as silicon or another semiconductor material, coupled between the backside surface and the array of photosensitive regions 304A, 304B. The light may be transmitted into the material toward the array of photosensitive regions.

Provided that there the material has sufficient thickness, at least some of the light may tend to free electrons (e⁻) in the material. In order to be detected, the electrons (e⁻) should move to the photosensitive regions. In addition, the electrons generated in material 308A should preferably move toward corresponding photosensitive region 304A, and the electrons generated in material 308B should preferably move toward corresponding photosensitive region 304B. However, there is a tendency for some of the electrons to diffuse, laterally drift, or otherwise migrate or move away from their corresponding photosensitive region, and in some cases may be collected by a neighboring photosensitive region. Electrons generated near the edge tend to have a higher likelihood of migrating to a neighboring photosensitive region than electrons generated near the center. Such electrical crosstalk may cause blurring, poor color performance, or other image artifacts and is generally undesirable. As discussed below, the photodetector array has electron lenses to reduce such crosstalk.

An array of hemi-spheroidal protuberances or convexities 309A, 309B is formed in the material. Each of the convexities or hemispheroidal protuberances corresponds to, and protrudes away from, a respective one of the photosensitive regions. The protuberances or convexities are shown in two-dimensional cross-section, although it is to be understood that the convexities or hemispheroidal protuberances have three-dimensional convex or hemispheroidal surfaces that face away from the corresponding photosensitive regions.

The photodetector array also includes a non-flat layer 310. The non-flat layer 310 is coupled between the backside surface 302A, 302B and the array of hemi-spheroidal protuberances or convexities 309A, 309B. In the illustration, the non-flat layer is formed directly on the array of hemi-spheroidal protuberances or convexities.

The non-flat layer has an array of recessed portions 310A, 310B. Each of the recessed portions 310A, 310B corresponds to, and recedes away from, a respective one of the array of photosensitive regions 304A, 304B. Also, each of the recessed portions 310A, 310B corresponds to, and conforms to, a respective one of the hemi-spheroidal protuberances or convexities 309A, 309B.

The recessed portions 310A, 310B of the non-flat layer 310 represent respective electron lenses 310A, 310B for the corresponding photosensitive regions 304A, 304B. The electron lens 310A has a concave-convex shape including a concave surface 314 facing the photosensitive region 304A and a convex surface 316 facing the microlens 302A.

The electron lens 310A is to focus or converge electrons in the material 308A toward corresponding photosensitive region 304A. Likewise, the electron lens 310B is to focus or converge electrons in the material 308B toward corresponding photosensitive region 304B. This may help to reduce the likelihood that an electron will migrate to a neighboring photosensitive region and/or help to reduce electrical crosstalk.

The non-flat layer is capable of generating an electron focusing or converging electric field in the array of hemi-spheroidal protuberances or convexities. The right-hand side of the illustration shows representative electron converging or focusing lines of force 312B of the electric field for electron lens 310B. A similar electron converging or focusing electric field would be generated by electron lens 310A.

The non-flat layer is also capable of optically focusing light. In other words, the electron lenses are also converging optical lenses. The left-hand side of the illustration shows how light 303 represented by arrows may be optically focused by the electron lens 310A. The light may bend toward the center of the photodetector 304A as it passes from the electron lens 310A into the material 308A. For example, it may be caused by the shape of the electron lens 310A and the refractive index difference between the electron lens 310A and planarization layer 336. This optical focusing may help to reduce optical crosstalk.

Different types of layers are capable of generating an electric field in the material. In one or more embodiments, non-flat layer 310 may include a heavily doped semiconductor material, and the material 308A, 308B may include less heavily doped semiconductor material.

As is known, a semiconductor may be doped with a dopant to alter its electrical properties. Dopants may either be acceptors or donors.

Acceptor dopant elements generate excess holes in the semiconductor whose atoms they replace by accepting electrons from those semiconductor atoms. Suitable acceptors for silicon include boron, indium, gallium, aluminum, and combinations thereof.

Donor dopant elements generate excess electrons in the semiconductor whose atoms they replace by donating electrons to semiconductor atoms. Suitable donors for silicon include phosphorous, arsenic, antimony, and combinations thereof.

A “p-type semiconductor”, a “semiconductor of p-type conductivity”, or the like, refers to a semiconductor doped with an acceptor, and in which the concentration of holes is greater than the concentration of free electrons. The holes are majority carriers and dominate conductivity.

An “n-type semiconductor”, a “semiconductor of n-type conductivity”, or the like, refers to a semiconductor doped with a donor and in which the concentration of free electrons is greater than the concentration of holes. The electrons are majority carriers and dominate conductivity.

P-type and n-type semiconductors are generally doped with light to moderate concentrations of dopant. In one or more embodiments, p-type and n-type semiconductors have concentrations of dopant that are less than about 1×10¹⁵ dopants/cm³.

A “p+ semiconductor”, a “p+ doped semiconductor”, a “semiconductor of p+ conductivity”, or the like, refers to a heavily doped p-type semiconductor that is heavily doped with donor elements. A “n+ semiconductor”, a “n+ doped semiconductor”, a “semiconductor of n+ conductivity”, or the like, refers to a heavily doped n-type semiconductor that is heavily doped with acceptor elements. In one or more embodiments, p+ doped semiconductors and n+ doped semiconductors have concentrations of dopant that are more than about 1×10¹⁵ dopants/cm³, sometimes more than about 1×10¹⁶ dopants/cm³.

In one or more embodiments, the non-flat layer 310 may include a heavily doped semiconductor material, and the material 308A, 308B may include a light to moderately doped semiconductor material. For example, the non-flat layer 310 may include a p+ doped semiconductor material, and the material 308A, 308B may include a p-type semiconductor material. In such an example, the photosensitive regions 304A, 304B may be n-type. Opposite polarity configurations are also suitable. For example, the non-flat layer 310 may include a n+ doped semiconductor material, the material 308A, 308B may include a n-type semiconductor material, and the photosensitive regions 304A, 304B may be p-type.

A thickness of the layers of the heavily doped semiconductor material may range from about 10 nanometers (nm) to about 400 nm. In some cases the thickness may range from about 50 nm to about 200 nm.

In one or more embodiments of the invention, an optional doping concentration gradient or slope may exist across the thickness of the non-flat layer. For example, the non-flat layer may have a greater dopant concentration at a backside portion (e.g., 316) thereof and a lesser dopant concentration at a frontside portion (e.g., 314) thereof. In one or more embodiments, the greater dopant concentration at the backside portion may range from about 1×10¹⁷ dopants/cm³ to about 1×10²⁰ dopants/cm³. In one or more embodiments, the lesser dopant concentration at the frontside portion may range from about 1×10¹⁴ dopants/cm³ to about 2×10¹⁵ dopants/cm³. A relatively steep concentration gradient tends to work well.

The photodetector array also includes a first optional planarization layer 336 coupled between the array of microlenses 330A, 330B and the non-flat layer 310. The front side of the first planarization layer conforms to the non-flat surface (e.g., 316). The first planarization layer has a backside surface that is planar or flat. The electron lenses are disposed between the material 308A, 308B and the planarization layer 336.

The photodetector array also includes an optional array of different color filters 334A, 334B coupled between the array of electron lenses 310A, 310B and the array of optical microlenses 330A, 330B. In particular, the color filters are coupled between the flat surface of the planarization layer and the optical microlenses. The color filter 334A is operable to filter a different color than the color filter 334B. These color filters are optional and not required. For example, these color filters may be omitted in the case of a black and white image sensor.

The photodetector array also includes a second optional planarization layer 332 coupled between the array of color filters and the array of optical microlenses. However, the second planarization layer is optional and not required.

The photodetector array includes an interconnect portion 342 at the front side thereof. The interconnect portion may include one or more conventional metal interconnect layers disposed within dielectric material. Optional shallow trench isolation (STI) 338 is included between adjacent photosensitive regions, although the STI is not required. Optional pinning layers 340, such as, for example, p+ doped regions in the case of n-type photosensitive regions, are disposed on the front surfaces of each of the photosensitive regions.

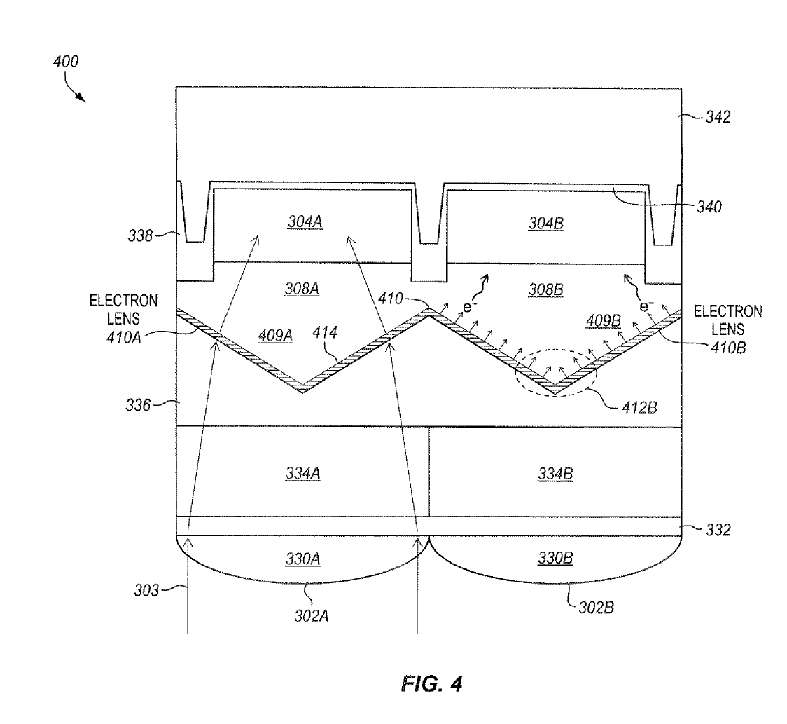

FIG. 4 is a cross-sectional side view of another photodetector array 400, according to one or more embodiments of the invention. The photodetector array is a BSI photodetector array.

The photodetector array 400 shown in FIG. 4 has certain features in common with the photodetector array 300 shown in FIG. 3. Where considered appropriate, certain components or structures in FIG. 4 have been labeled with the prior reference numbers from FIG. 3. Unless otherwise specified, this indicates that these components or structures may optionally have some or all of the previously described characteristics or attributes. To avoid obscuring certain concepts, the following description will focus primarily on the different structures and characteristics of the photodetector array 400 shown in FIG. 4.

A significant difference between the photodetector array 400 and the previously described photodetector array 300 is the shapes of the array of protuberances 409A, 409B, the non-flat layer 410, and the electron lenses 410A, 410B.

The photodetector array includes an array of protuberances 409A, 409B formed in material 308A, 308B. In one or more embodiments, each of the protuberances has the shape of a frustum. The frustum may represent a protuberance having the shape, for example, of a pyramid or truncated pyramid. By way of example, the pyramid may have three or four sides.

The photodetector array also includes the non-flat layer 410. The non-flat layer is formed directly on the array of protuberances. The non-flat layer has an array of recessed portions 410A, 410B. Each of the recessed portions 410A, 410B corresponds to, and conforms to, a respective one of the protuberances 409A, 409B. Also, each of the recessed portions 410A, 410B corresponds to, and recedes away from, a respective one of the array of photosensitive regions 304A, 304B.

The recessed portions 410A, 410B represent respective electron lenses 410A, 410B for the corresponding photosensitive regions 304A, 304B. The electron lens 410A has a recessed surface 414 facing the photosensitive region 304A. The recessed surface includes angled sidewalls that substantially conform to the angled sidewalls of the corresponding protuberance 409A having the shape of a frustum.

A representative electron converging or focusing lines of force 412B of an electric field is shown for electron lens 410B. The electron lines of force 412B is directed inwardly from angled sidewalls of the recessed surface of the electron lens 410B. The electric field drives electrons to focus or converge inwardly in three dimensions toward the photosensitive region 304B. A similar electric field would be generated by electron lens 410A.

Other aspects of the non-flat layer, such as, for example, materials (for example a heavily doped semiconductor material), thickness, doping gradients, and the like, may optionally be as previously described.

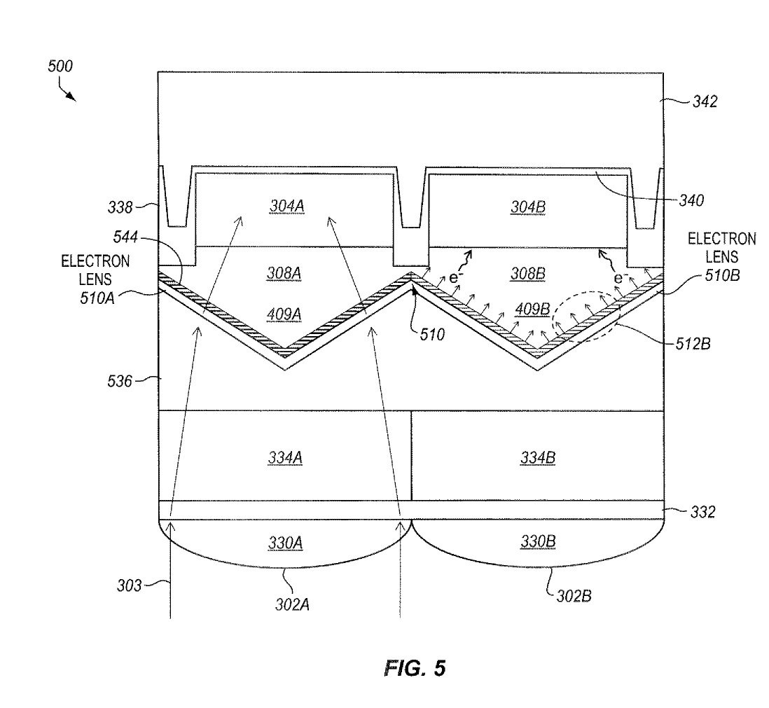

FIG. 5 is a cross-sectional side view of yet another photodetector array 500, according to one or more embodiments of the invention. The photodetector array is a BSI photodetector array.

The photodetector array 500 shown in FIG. 5 has certain features in common with the photodetector array 300 shown in FIG. 3 and/or the photodetector array 400 shown in FIG. 4. Notice that the shapes of the array of protuberances and the non-flat layer in the photodetector array 500 of FIG. 5 are similar to those of the photodetector array 400 of FIG. 4. Where considered appropriate, certain components or structures in FIG. 5 have been labeled with the previous reference numbers from FIG. 3 or FIG. 4. Unless otherwise specified, these components or structures may optionally have some or all of the previously described characteristics or attributes. To avoid obscuring certain concepts, the following description will focus primarily on the different structures and characteristics of the photodetector array 500 shown in FIG. 5.

One significant difference between the photodetector array 500 and the previously described photodetector array 300 and 400 is the material used for the non-flat layer 510 and/or the electron lenses 510A, 510B. Another difference is the way the electron lenses generate the electric fields used to focus or converge the electrons toward the photosensitive regions.

The photodetector array 500 includes the non-flat layer 510. The non-flat layer is formed over an array of protuberances 409A, 409B, which are formed in a material 308A, 308B. As before, each of the protuberances may have the shape of a pyramid or other frustum. The non-flat layer has recessed portions 510A, 510B. These recessed portions represent respective electron lenses 510A, 510B for the corresponding photosensitive regions 304A, 304B.

In one or more embodiments of the invention, the non-flat layer 510 may include a thin metal layer. The layer may be sufficiently thin to allow light to pass through it. The layer may be operable to create a hole accumulation region in adjacent portion of the material 409A, 409B. For example, the layer 510 may include a metal having a workfunction sufficiently high to create the hole accumulation region. Platinum is one specific example of a metal that is operable to create a hole accumulation region in an adjacent silicon material. In one or more embodiments, the non-flat layer 510 may include a flash gate. The flash gate or thin metal film may optionally be negatively biased to further populate the adjacent material with holes. Flash gates are known in the arts of photodetectors, such as, for example, in conjunction with CCDs.

Referring again to FIG. 5, a hole accumulation region 544 is formed in the material 409A, 409B. The hole accumulation region 544 formed in the material 409A, 409B has a greater concentration of holes than the bulk of the material 409A, 409B. This greater concentration of holes may create an electric field in the material. A representative electron converging or focusing lines of force 512B of an electric field is shown for electron lens 510B. A similar electron converging or focusing electric field would be generated by electron lens 510A.

The flash gate or other thin metal layer may also optionally be used for protuberances and electron lenses shaped like those of FIG. 3.

Still other materials are also suitable for the electron lenses. In one or more embodiments, the electron lenses may include one or more of a transparent conductive oxide (TCO) and a transparent conductive coating (TCC). Examples of suitable TCOs include, but are not limited to, oxides of indium combined with oxides of tin (e.g., indium(III) oxide (In₂O₃) plus tin(IV) oxide (SnO₂)), oxides of zinc combined with oxides of aluminum (e.g., zinc oxide (ZnO) plus aluminum oxide (Al₂O₃), oxides of zinc combined with oxides of gallium (e.g., zinc oxide (ZnO) plus gallium (III) oxide (Ga₂O₃), and oxides of tin (e.g., tin oxide (SnO₂), to name just a few examples. Examples of suitable TCCs include, but are not limited to, a thin gold film, a heat resistive conductive plastic, and layers including carbon nanotubes, to name just a few examples.

When the electron lenses are electrically negatively biased, holes in the material 409A/409B may be attracted toward the electron lenses 510A/510B. This may generate hole accumulation regions in the material, which in turn may create electric fields in the material 409A/409B. In one or more embodiments, a thin semiconductor oxide film may optionally be disposed between the non-flat layer 510 and the hole accumulation region 544 formed in the material 409A, 409B. In one aspect, this oxide film may include an oxide of silicon, such as, for example, silicon dioxide (SiO₂). When the electron lenses are negatively biased, the thin semiconductor oxide film may help to improve device reliability and/or to help to reduce malfunctions in devices disposed in the light detection portion of the substrate.

In photodetector arrays, the incident angle of light may gradually increase from the center of the array (zero degree incident angle) to the periphery of the array. In one or more embodiments, the optical microlenses and/or the electron lenses may optionally be scaled or offset in peripheral regions of the array based on the angle of incident light. For example, the optical microlenses and/or the electron lenses toward the center of the array may be aligned relatively directly above or below their corresponding photosensitive regions, while the optical microlenses and/or the electron lenses in the peripheral regions of the array may be shifted slightly inwardly toward the center of the array to account for the different angles of the incident light. This may help to improve imaging, but is optional and not required.

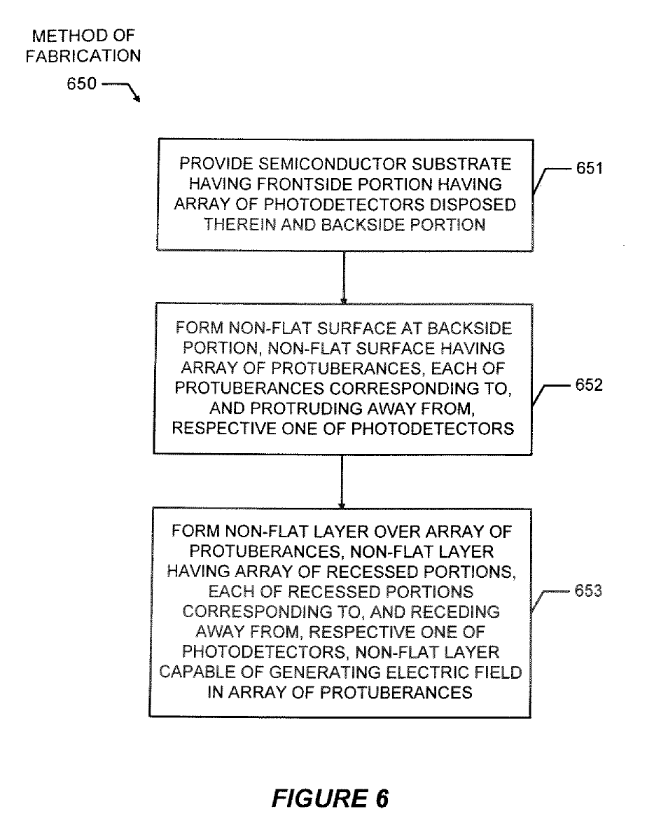

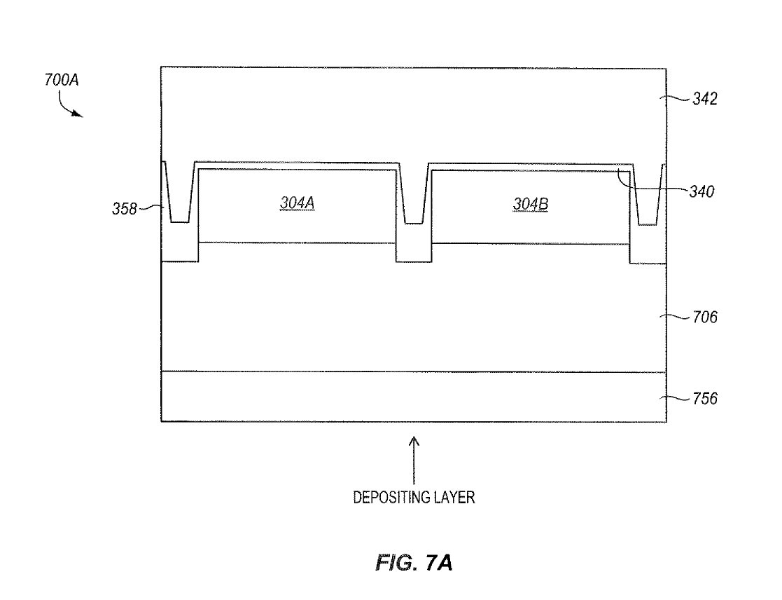

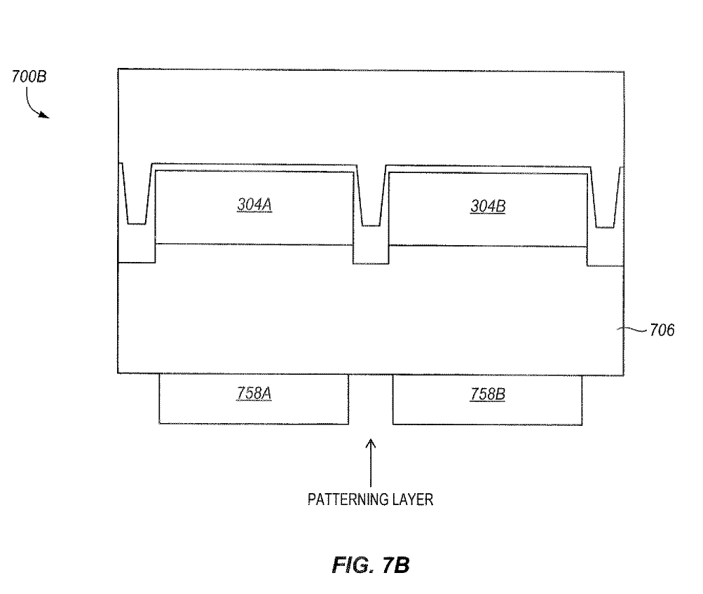

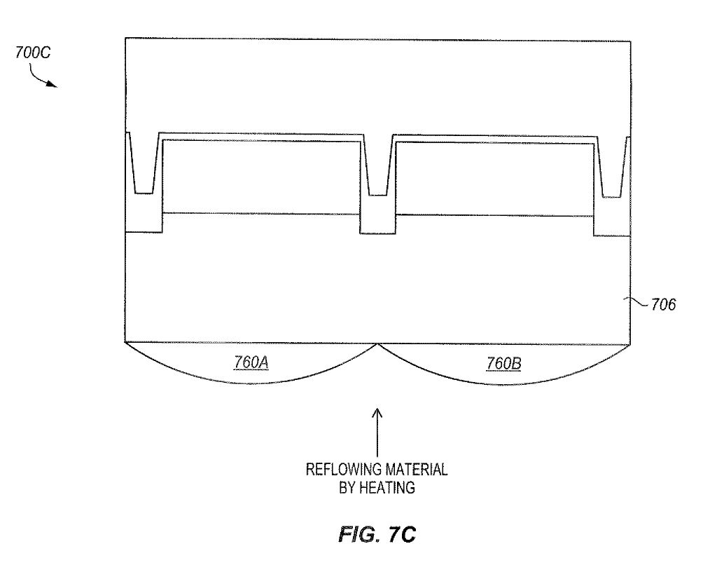

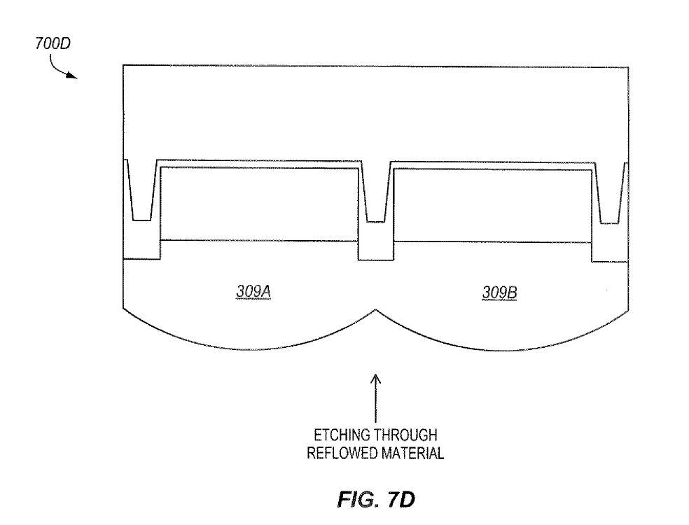

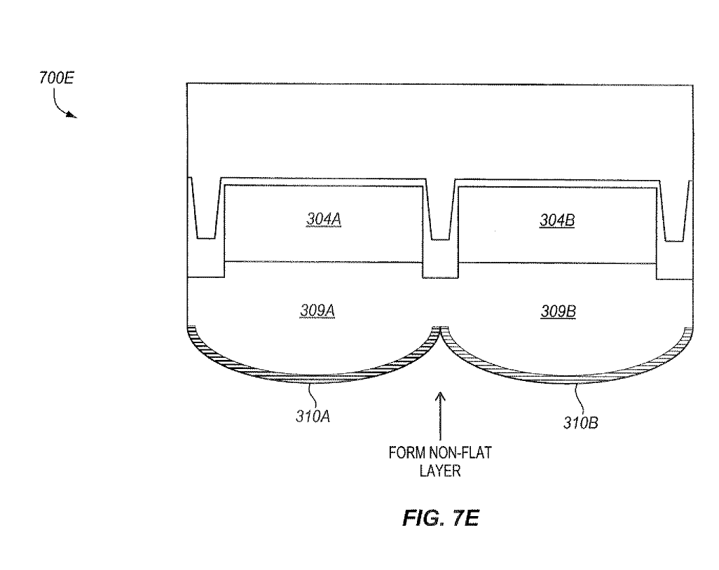

FIG. 6 is a block flow diagram of a method 650 of making or fabricating a photodetector array, according to embodiments of the invention. The method 650 may be performed to fabricate any of the photodetectors or photodetector arrays shown in FIG. 1, 3, 4, or 5, or other photodetector arrays entirely. FIGS. 7A to 7E illustrate various structures that may be formed while carrying out the method 650. For clarity, the method 650 of FIG. 6 will be described in association with the structures shown in FIGS. 7A to 7E.

The method 650 includes providing a substrate, at block 651. As used herein, the term “providing” is intended to broadly encompass at least fabricating, obtaining from another, purchasing, importing, and otherwise acquiring the substrate. The substrate has a frontside portion having an array of photosensitive regions disposed therein and a backside portion.

A non-flat surface may be formed at the backside portion of the substrate, at block 652. The non-flat surface may have an array of protuberances. Each of the protuberances may correspond to, and may protrude away from, a respective one of the photosensitive regions.

There are different ways of forming such a non-flat surface. FIGS. 7A-7D are cross-sectional side views of substrates illustrating one example way of forming the non-flat surface that utilizes a reflowable material.

FIG. 7A shows depositing a layer 756 of a reflowable material over a backside semiconductor portion 706 of a substrate 700A. The substrate also has a frontside interconnect portion 342, a frontside semiconductor portion having an array of photosensitive regions 304A, 304B disposed therein, STI 358, and the backside semiconductor portion 706. These components may be substantially as previously described. In one embodiment, the reflowable material may comprise a poly methyl-methacrylate material, although this is not required.

FIG. 7B shows a substrate 700B including a patterned layer including an array of reflowable material portions 758A, 758B formed by patterning the layer 756 of the reflowable material of the substrate 700A. The patterning may be performed by lithography and development. Each of the reflowable material portions corresponds to a respective one of the photosensitive regions 304A, 304B.

FIG. 7C shows a substrate 700C including an array of hemispheroidal reflowable material protuberances 760A, 760B forming by reflowing the array of reflowable material portions 758A, 758B of the substrate 700B. This may be accomplished by heating the material to temperature above its reflow temperature.

FIG. 7D shows a substrate 700D having a non-flat backside surface including an array of hemispheroidal protuberances 309A, 309B etched in the backside semiconductor portion 706 of the substrate 700C. The etching into the backside semiconductor portion 706 is performed through the array of hemispheroidal reflowable material protuberances 760A, 760B of the substrate 700C. In this way, the non-flat surface of the hemispheroidal reflowable material protuberances is transferred as a somewhat conforming non-flat surface in the backside semiconductor portion 706. The surfaces may not be exactly hemispherical, due to the reflowed meniscus and possible differences in etching rates between the materials, but the term “hemispheroidal” is intended to encompass such deviations.

FIGS. 7A-7D illustrate one example approach for forming the non-flat surface. As another example, a non-flat surface may be formed with the use of gray level masks. As yet another option, directional etching of silicon along crystallographic planes may optionally be utilized.

Referring again to FIG. 6, after forming the non-flat surface at block 652, a non-flat layer may be formed over the array of protuberances, at block 653. The non-flat layer may be capable of generating an electric field in the array of protuberances. The non-flat layer may have an array of recessed portions. Each of the recessed portions may correspond to, and may recede away from, a respective one of the photosensitive regions. Each of the recessed portions may represent an electron lens.

FIG. 7E shows a substrate 700E having a non-flat layer 310A, 310B over the array of hemispheroidal protuberances 309A, 309B. A first portion of the layer over first protuberance 309A may represent a first electron lens 310A and a second portion of the layer over second protuberance 309B may represent a second electron lens 310B.

In one or more embodiments, the non-flat layer may be a heavily doped layer, such as, for example, a p+ doped layer or an n+ doped layer. Such a layer may be formed by doping. The doping may be performed by ion implantation or diffusion. Annealing may be used. In one or more embodiments, the heavily doped layer may be formed to have a thickness that ranges from about 10 nm to about 400 nm, in some cases from about 80 nm to about 200 nm. As previously described, in one or more embodiments of the invention, a doping concentration gradient or slope may exist across the thickness of the non-flat layer.

Alternatively, in one or more embodiments, the non-flat layer may include a metal flash gate or other thin metal film. In one or more embodiments, the metal flash gate or thin metal film may be formed by flashing from about 3 to about 20 Angstroms of platinum or another suitable metal. The flash gate or thin metal film may optionally be negatively biased to further populate the adjacent semiconductor with holes.

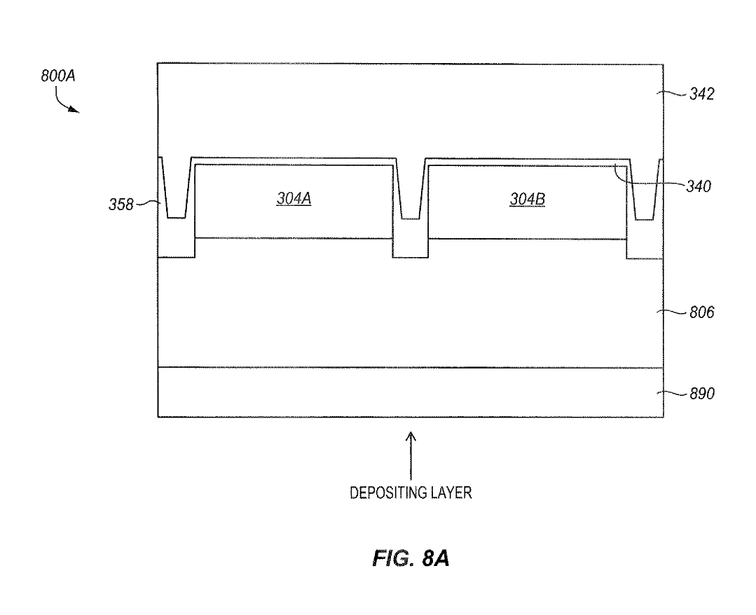

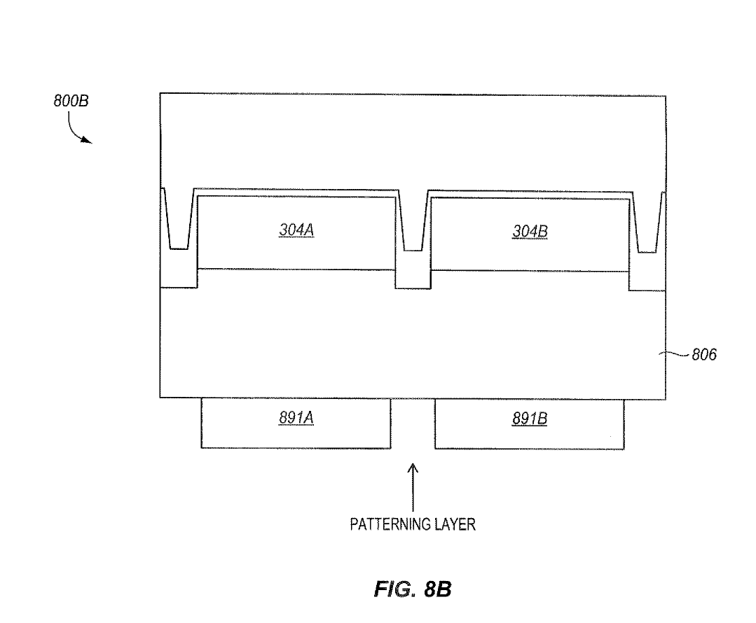

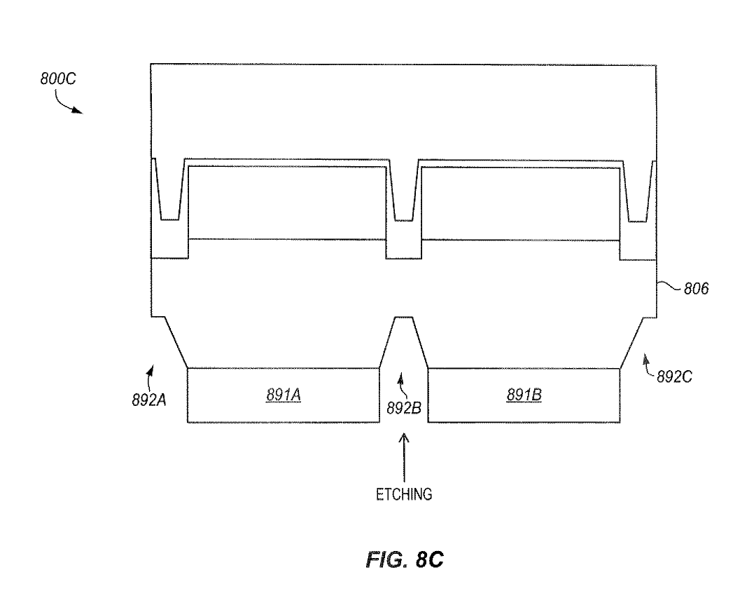

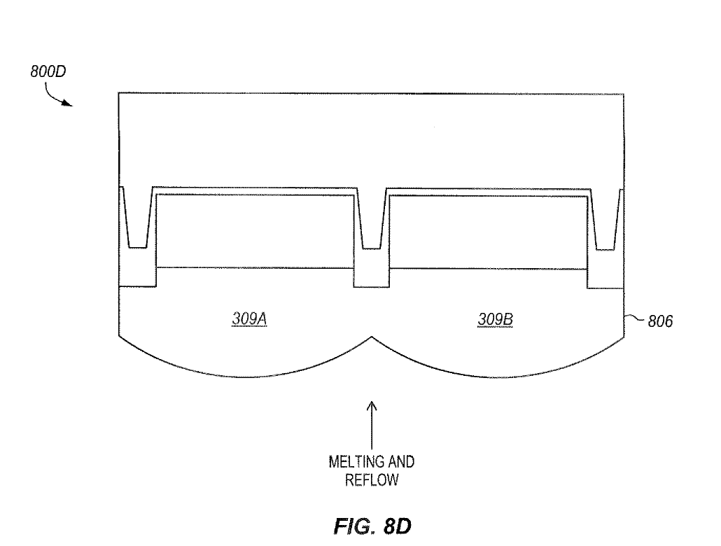

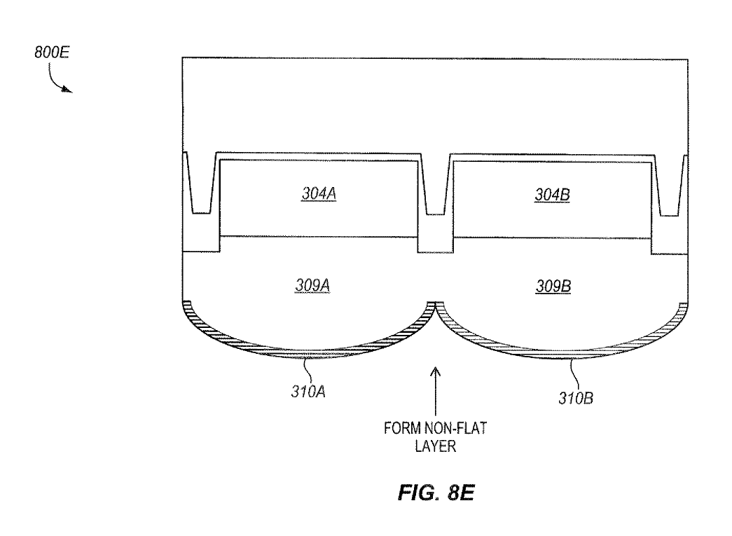

Other embodiments of the method 650 of making or fabricating a photodetector array as shown in FIG. 6 are also contemplated. FIGS. 8A to 8E illustrate various structures formed while carrying out one or more other embodiments of the method of FIG. 6. Notably, FIGS. 8A to 8E show a different approach for forming a non-flat surface at a backside portion of a substrate.

FIG. 8A shows depositing a masking layer 890, such as, for example, a photoresist, over a backside semiconductor portion 806 of a substrate 800A. The masking layer 890 may be formed by depositing and spinning a photoresist, for example. The substrate also has a frontside interconnect portion 342, a frontside semiconductor portion having an array of photosensitive regions 304A, 304B disposed therein, STI 358, and the backside semiconductor portion 806. These components may be substantially as previously described.

FIG. 8B shows a substrate 800B including a patterned masking layer 891A, 891B formed by patterning the masking layer 890 of the substrate 800A. The patterning may be performed by lithography and development. The patterned masking layer includes an array of mask portions 891A, 891B. Each of the mask portions corresponds to a respective one of the photosensitive regions 304A, 304B. As shown, there is a gap between the array of mask portions 891A, 891B.

FIG. 8C shows a substrate 800C including grooves 892A, 892B, 892C etched in the backside portion 806 of the substrate 800B. The grooves may be formed by etching into the backside portion through the patterned mask layer. In one or more embodiments, the grooves may have a depth ranging from about 0.1 to about 0.5 microns. Various etches with selectivity for the backside portion 806 relative to the masking layer are suitable.

FIG. 8D shows a substrate 800D having a non-flat backside surface including an array of hemispheroidal protuberances 309A, 309B formed from the etched backside portion 806 of the substrate 800C. Initially, the patterned masking layer 891A, 891B may be removed, such as, for example, by stripping. Then a surface portion of the remaining backside semiconductor portion 806 may be melted and reflowed by heating the surface portion to a temperature above its melting point. In one or more embodiments, the surface portion that is melted includes silicon or another semiconductor material. In one or more embodiments, this heating may be performed by laser annealing to a temperature sufficient to melt silicon. The melted surface portions between the grooves may reflow to form an array of generally hemispheroidal protuberances each corresponding to one of the photosensitive regions.

FIG. 8E shows a substrate 800E having a non-flat layer 310A, 310B formed over the array of hemispheroidal protuberances 309A, 309B of the substrate 800D. A first portion of the layer over first protuberance 309A may represent a first electron lens 310A and a second portion of the layer over second protuberance 309B may represent a second electron lens 310B. This non-flat layer 310A, 310B may be formed as previously described.

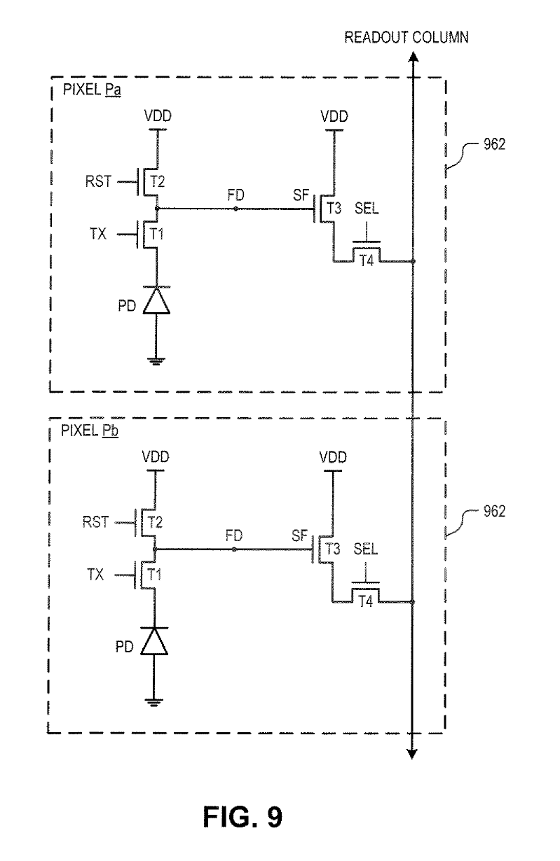

FIG. 9 is a circuit diagram illustrating example pixel circuitry 962 of two four-transistor (4T) pixels of a photodetector array, according to one or more embodiments of the invention. The pixel circuitry is one possible way of implementing these two pixels. However, embodiments of the invention are not limited to 4T pixel architectures. Rather, 3T designs, 5T designs, and various other pixel architectures are also suitable.

In FIG. 9, pixels Pa and Pb are arranged in two rows and one column. The illustrated embodiment of each pixel circuitry includes a photodiode PD, a transfer transistor T1, a reset transistor T2, a source-follower (SF) transistor T3, and a select transistor T4. During operation, transfer transistor T1 may receive a transfer signal TX, which may transfer the charge accumulated in photodiode PD to a floating diffusion node FD. In one embodiment, floating diffusion node FD may be coupled to a storage capacitor for temporarily storing image charges.

Reset transistor T2 is coupled between a power rail VDD and the floating diffusion node FD to reset the pixel (for example discharge or charge the FD and the PD to a preset voltage) under control of a reset signal RST. The floating diffusion node FD is coupled to control the gate of SF transistor T3. SF transistor T3 is coupled between the power rail VDD and select transistor T4. SF transistor T3 operates as a source-follower providing a high impedance connection to the floating diffusion FD. Select transistor T4 selectively couples the output of pixel circuitry to the readout column line under control of a select signal SEL.

In one embodiment, the TX signal, the RST signal, and the SEL signal are generated by control circuitry. In an embodiment where photodetector array operates with a global shutter, the global shutter signal is coupled to the gate of each transfer transistor T1 in the entire array to simultaneously commence charge transfer from each pixel's photodiode PD. Alternatively, rolling shutter signals may be applied to groups of transfer transistors T1.

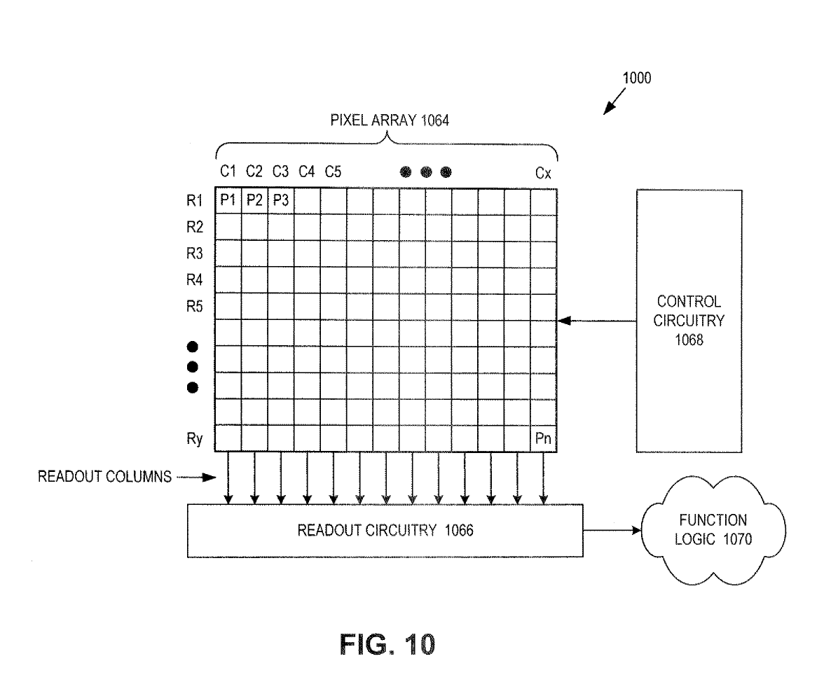

FIG. 10 is a block diagram illustrating a backside illuminated image sensor unit 1000, according to one or more embodiments of the invention. The image sensor unit includes a pixel array 1064, readout circuitry 1066, control circuitry 1068, and function logic 1070. In alternate embodiments, one or both of function logic 1070 and control circuitry 1068 may optionally be included outside of image sensor unit.

The pixel array is a two-dimensional (2D) array of backside illuminated pixels (e.g., pixels P1, P2, . . . Pn). In one embodiment, each pixel is an active pixel sensor (APS), such as a complementary metal-oxide-semiconductor (CMOS) imaging pixel. As illustrated, each pixel is arranged into a row (e.g., rows R1 to Ry) and a column (e.g., column C1 to Cx) to acquire image data of a person, place, or object, which can then be used to render a 2D image of the person, place, or object.

After each pixel has acquired its image data or image charge, the image data is readout by the readout circuitry 1066 and transferred to the function logic 1070. The readout circuitry may include amplification circuitry, analog-to-digital conversion circuitry, or otherwise. The function logic may simply store the image data or even manipulate the image data by applying post image effects (e.g., crop, rotate, remove red eye, adjust brightness, adjust contrast, or otherwise). As shown, in one embodiment, the readout circuitry may readout a row of image data at a time along readout column lines. Alternatively, the readout circuitry may readout the image data using a variety of other techniques, such as a serial readout, or a full parallel readout of all pixels simultaneously.

The control circuitry 1068 is coupled to the pixel array to control operational characteristics of the pixel array. For example, the control circuitry may generate a shutter signal for controlling image acquisition.

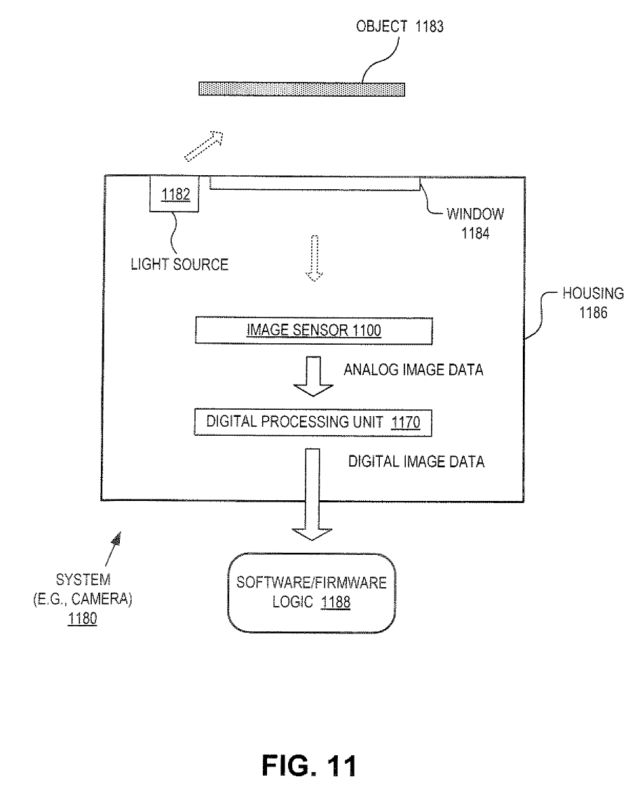

FIG. 11 is a block diagram illustrates an illumination and image capture system 1180 incorporating an image sensor unit 1100, according to one or more embodiments of the invention. In various embodiments, the system may represent or be incorporated within a digital camera, a digital camera phone, a web camera, a security camera, an optical mouse, an optical microscope, or a scanner, to name just a few examples.

The system includes a light source 1182, such as, for example, multicolor light emitting diodes (LEDs) or other semiconductor light sources. The light source may transmit light to an object 1183 being imaged.

At least some light reflected by the object may be returned to the system through a window 1184 of a housing 1186 to the image sensor unit 1100. The window is to be interpreted broadly as a lens, cover, or other transparent portion of the housing. The image sensor unit may sense the light and may output analog image data representing the light or image.

A digital processing unit 1170 may receive the analog image data. The digital processing unit may include analog-to-digital (ADC) circuitry to convert the analog image data to corresponding digital image data.

The digital image data may be subsequently stored, transmitted, or otherwise manipulated by software/firmware logic 1188. The software/firmware logic may either be within the housing, or as shown external to the housing.

In the above description and in the claims, the term “coupled” may mean that two or more elements are in direct physical or electrical contact. However, “coupled” may instead mean that two or more elements are not in direct contact with each other, but yet still co-operate or interact with each other, such as, for example, through one or more intervening components or structures. For example, an electron lens may be coupled between a surface and a material with one or more intervening materials (for example a planarization layer, a color filter, etc.).

In the description above, for the purposes of explanation, numerous specific details have been set forth in order to provide a thorough understanding of the embodiments of the invention. It will be apparent however, to one skilled in the art, that other embodiments may be practiced without some of these specific details. The particular embodiments described are not provided to limit the invention but to illustrate it. The scope of the invention is not to be determined by the specific examples provided above but only by the claims below. In other instances, well-known circuits, structures, devices, and operations have been shown in block diagram form or without detail in order to avoid obscuring the understanding of the description.

Reference throughout this specification to “one embodiment”, “an embodiment”, or “one or more embodiments”, for example, means that a particular feature may be included in the practice of the invention. Similarly, in the description various features are sometimes grouped together in a single embodiment, figure, or description thereof, for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. An apparatus comprising:
a surface to receive light;
a photosensitive region disposed within a substrate;
a material coupled between the surface and the photosensitive region, the material to receive the light, at least some of the light to free electrons in the material; and
an electron lens coupled between the surface and the material, the electron lens to focus the electrons in the material toward the photosensitive region.

2. The apparatus of claim 1, wherein the electron lens has a major surface that is not flat.

3. The apparatus of claim 2, wherein the major surface that is not flat comprises a recessed surface that recedes from the photosensitive region,

4. The apparatus of claim 3, wherein the recessed surface comprises a concave surface facing the photosensitive region.

5. The apparatus of claim 4, wherein the electron lens has a convex-concave shape including the concave surface facing the photosensitive region and a convex surface facing the surface that is to receive the light.

6. The apparatus of claim 1, wherein the electron lens comprises an optical and electron lens that has a focus for light in the material and the electrons that is proximate the photosensitive region.

7. The apparatus of claim 6, wherein the focus is within the photosensitive region.

8. The apparatus of claim 1, wherein the material comprises a semiconductor material, and wherein the electron lens comprises a layer of a heavily doped semiconductor material, the heavily doped semiconductor material being more heavily doped than the semiconductor material.

9. The apparatus of claim 8, wherein the semiconductor material comprises a p-type semiconductor material, wherein the heavily doped semiconductor material comprises a p+ doped semiconductor material, and wherein a thickness of the p+ doped semiconductor material ranges from 10 nanometers to 400 nanometers.

10. The apparatus of claim 9, wherein a doping concentration gradient exists across a thickness of the heavily doped semiconductor material.

11. The apparatus of claim 1, wherein the electron lens comprises a thin metal layer over the material that is sufficiently thin to allow light to pass through and that is operable to create a hole accumulation region in an adjacent portion of the material.

12. The apparatus of claim 1, wherein the electron lens also is operable to optically focus light toward the photosensitive region.

13. The apparatus of claim 1, wherein the surface comprises a surface of an optical microlens that is aligned to focus the light toward the photosensitive region, and further comprising:
a planarization layer having a flat surface coupled between the optical microlens and the electron lens; and
a color filter coupled between the flat surface of the planarization layer and the optical microlens.

14. The apparatus of claim 1, wherein the apparatus comprises an image sensor, wherein the photosensitive region is one of an array of photosensitive regions of the image sensor, wherein the image sensor comprises a backside illuminated image sensor.

15. An apparatus comprising:
a surface to receive light;
a photosensitive region disposed within a substrate;
a material coupled between the surface and the photosensitive region, the material to receive the light, at least some of the light to free electrons in the material; and
an optical and electron lens coupled between the surface and the material, the optical and electron lens to focus the light and the electrons in the material toward the photosensitive region.

16. The apparatus of claim 15, wherein the optical and electron lens has a major surface that is not flat, wherein the major surface that is not flat comprises a recessed surface that recedes from the photosensitive region, and wherein the optical and electron lens has a focus for the light and the electrons that is proximate the photosensitive region.

17. The apparatus of claim 15, wherein the material comprises a semiconductor material, and wherein the optical and electron lens comprises a layer of a heavily doped semiconductor material, the heavily doped semiconductor material being more heavily doped than the semiconductor material.

18. A method comprising:
providing a substrate having a frontside portion having an array of photosensitive regions disposed therein and a backside portion;
forming a non-flat surface at the backside portion, the non-flat surface having an array of protuberances, each of the protuberances corresponding to, and protruding away from, a respective one of the photosensitive regions;
forming a non-flat layer over the array of protuberances, the non-flat layer having an array of recessed portions, each of the recessed portions corresponding to, and receding away from, a respective one of the photosensitive regions, the non-flat layer capable of generating an electric field in the array of protuberances.

19. The method of claim 18, wherein said forming the non-flat layer comprises one of:
forming a heavily doped semiconductor material that is more heavily doped than a material of the array of protuberances; and
depositing a thin metal layer that is sufficiently thin to allow light to pass through and that is operable to create a hole accumulation region in the array of protuberances

20. The method of claim 18, wherein said forming the non-flat surface comprises:
depositing a layer of a reflowable material over the backside portion;
patterning the layer of the reflowable material to form a patterned layer by lithography and development, the patterned layer including an array of reflowable material portions, each of the reflowable material portions corresponding to a respective one of the photosensitive regions;
forming an array of hemi-spheroidal reflowable material protuberances by reflowing the array of reflowable material portions by heating; and
etching the array of hemi-spheroidal protuberances in the backside portion by etching into the backside portion through the array of hemi-spheroidal reflowable material protuberances.

21. The method of claim 18, wherein said forming the non-flat surface comprises:
forming a patterned mask layer over the backside portion by lithography and development, the patterned mask layer including an array of mask portions, each of the mask portions corresponding to a respective one of the photosensitive regions;
etching the backside portion through the patterned mask layer to form grooves in the backside portion between the mask portions of the patterned mask layer;
removing the patterned mask layer;
forming the non-flat surface by melting and reflowing portions of the backside portion between the grooves.

22. A method comprising:
receiving light at a surface;
transmitting the light toward a photosensitive region;
freeing electrons in a material with the light;
focusing the electrons in the material toward the photosensitive region; and
receiving the electrons at the photosensitive region.

23. The method of claim 23, wherein said focusing the electrons comprises focusing the electrons toward the photosensitive region in three dimensions with an electron converging electric field that drives electrons to converge toward the photosensitive region in three dimensions, and wherein said focusing the electrons comprises focusing the electrons with a non-flat layer having a recessed portion that recedes away from the photosensitive region.
